(19) United States
(12) Patent Application Publication
(10) Pub. No.: US 2024/0116760 A1
(43) Pub. Date: Apr. 11, 2024

(54) PELLICLE MEMBRANE FOR A LITHOGRAPHIC APPARATUS AND METHOD

(71) Applicant: ASML NETHERLANDS B.V., Veldhoven (NL)

(72) Inventors: Paul Alexander VERMEULEN, Eindhoven (NL); Zomer Silvester HOUWELING, Utrecht (NL)

(21) Appl. No.: 18/276,248

(22) PCT Filed: Feb. 3, 2022
(86) PCT No.: PCT/EP2022/052578

§ 371 Date: Aug. 7, 2023

(30) Foreign Application Priority Data
Mar. 5, 2021 (EP) 21160905.2

(51) Int. Cl. C01B 32/174; B01J 19/12; B01J 19/24; G03F 1/62; G03F 7/00

(52) U.S. Cl. CPC C01B 32/174; B01J 19/121; B01J 19/24; G03F 1/62; G03F 7/70983; B01J 2219/0886; B01J 2219/0896; B01J 2219/12; B82Y 30/00; C01B 2202/36

(57) ABSTRACT

A carbon nanotube membrane including carbon nanotubes having a pre-selected bonding configuration or (m, n) chirality, wherein the carbon nanotube membrane has a substantial amount of carbon nanotubes having zigzag (m, 0) chirality and/or armchair (m, m) chirality. An apparatus for the treatment of a carbon-based membrane, a method for treating carbon based membranes, pellicles including carbon based membranes, lithographic apparatuses includes carbon nanotube membranes, as well as the use of carbon nanotube membranes in lithographic apparatuses and methods are also described.

### CROSS-REFERENCE TO RELATED APPLICATIONS

This application claims priority of EP application 21160905.2 which was filed on Mar. 5, 2021 and which is incorporated herein in its entirety by reference.

The present invention relates to a carbon nanotube membrane, an apparatus for the treatment of a carbon nanotube membrane, a method for treating a carbon nanotube membrane, a pellicle comprising a carbon nanotube membrane, a lithographic apparatus comprising a pellicle or carbon nanotube membrane, and the use of a method, pellicle or carbon nanotube membrane in a lithographic method or apparatus. The present invention particularly relates to carbon nanotube membranes comprising carbon nanotubes having pre-selected bonding configuration or chirality. The present invention has particular, but not exclusive, application to EUV lithography apparatuses and methods.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously.

Since pellicles are in the optical path of the lithography apparatus, if the transmissivity of the pellicle varies over time during use, it may fall outside the allowable tolerances of the lithography apparatus and require replacement. It is therefore desirable to provide a pellicle which has a consistent transmissivity during use or at least which has a reduced rate of drift of transmissivity than previously.

A protective coating may be applied to a membrane material to protect the membrane material from being etched within the lithography apparatus. However, the protective coating may become damaged or separated from the membrane due to differences in the thermal expansion of the different materials.

The present invention has been devised in an attempt to address at least some of the problems identified above.

### SUMMARY OF THE INVENTION

According to a first aspect of the present invention, there is provided a carbon nanotube membrane comprising carbon nanotubes having a pre-selected bonding configuration or (m, n) chirality, characterised in that the carbon nanotube membrane comprises a substantial amount of carbon nanotubes having zigzag (m, 0) chirality and/or armchair (m, m) chirality. Determining the carbon nanotubes chirality can be done using spectroscopy and it is well known in the art.

By substantial amount, it is understood that the carbon nanotube membrane may comprise greater than around 65% of carbon nanotubes having zigzag (m, 0) chirality and/or armchair (m, m) chirality. The carbon nanotube membrane may comprise greater than around 70%, greater than around 75%, greater than around 80%, greater than around 85%, greater than around 90%, greater than around 95%, greater than around 98%, or greater than around 99% of carbon nanotubes having zigzag (m, 0) chirality and/or armchair (m, m) chirality. The amounts are provided as wt %.

There are a number of advantages provided by a carbon nanotube membrane comprising a substantial amount of carbon nanotubes having a pre-selected bonding configuration or chirality.

It has been found that CNTs with a pre-selected bonding configuration or chirality behave differently in a hydrogen plasma environment in a lithography apparatus. For example, CNTs with a zigzag chirality (m, 0) show a higher resistance to etching in hydrogen plasma environment than CNTs with other chirality, which makes them most suitable for films of uncoated CNTs having superior EUV transmission. Conversely, CNTs with armchair chirality (m, m) have a better thermal emissivity than CNTs with other chirality, which makes them more suitable for coated CNT applications having a superior thermal resistance. Therefore, depending on the conditions in the EUV lithographic apparatus it may be advantageous to have a pellicle or a membrane which comprises substantially CNTs with zigzag chirality, or CNTs with armchair chirality, or a combination of zigzag and armchair chirality having a specific ratio depending on the environmental conditions. Another advantage is that the drift in the transmissivity of a membrane according to the first aspect of the present invention is less than that of a carbon nanotube membrane which does not have a pre-selected bonding configuration or chirality. Since different carbon nanotubes may be more susceptible to depletion in a lithography apparatus, if such carbon nanotubes are depleted before the membrane is used in a lithography apparatus, then the transmissivity of the membrane will change less over time.

The carbon nanotubes may have a diameter of from around 1 nm to around 15 nm, preferably from around 2 nm to around 10 nm. Carbon nanotubes with larger diameters are more resistant to hydrogen plasma as compared to carbon nanotubes with smaller diameters.

The carbon nanotubes of armchair (m, m) chirality may include an etch-protective coating. Since the armchair carbon nanotubes have greater emissivity, they operate at lower temperature than other carbon nanotubes having different chirality. As such, in cases where low temperatures are preferred, the armchair nanotubes can be coated with a protective coating to prevent or at least reduce the rate at which they are etched by hydrogen plasma. Any suitable protective coating as known in the art may be used and the invention is not particularly limited by the coating selected.

The membrane may have a thickness of less than 100 nm. Since the membrane is intended for use in the path of a radiation beam, it is preferable for the membrane to be thin to allow the maximum amount of radiation to pass therethrough.

The membrane may have an EUV transmissivity of greater than around 90%, greater than around 92%, or greater than around 95%.

The membrane may be homochiral. By homochiral, it is understood that the membrane essentially comprises only one type of bonding configuration or chirality of carbon nanotubes.

According to a second aspect of the present invention, there is provided an apparatus for the treatment of a carbon-based membrane to obtain a pre-selected bonding configuration or chirality, the apparatus including a heat source and a gas supply, characterised in that the heat source and the gas supply are configured to treat at least part of the carbon-based membrane with a reactive gas or plasma formed from the reactive gas to selectively remove carbon nanotubes with a (m, n) chirality other than (m, 0) and (m, m) chirality from the carbon-based membrane, such that the treated carbon-based membrane comprises ≥65% of carbon nanotubes having zigzag and/or armchair chirality. In embodiments, the carbon-based membrane comprises greater than around 70%, greater than around 75%, greater than around 80%, greater than around 85%, greater than around 90%, greater than around 95%, greater than around 98%, or greater than around 99% of carbon nanotubes having zigzag (m, 0) chirality and/or armchair (m, m) chirality.

As the power of EUV lithography apparatuses increases, the thermal load to which pellicles and membranes are subject also increases. Carbon nanotube (CNT) membranes are especially suitable for use in EUV lithography due high EUV transmission and good mechanical robustness. Membranes which are based on carbon may include carbon in the form of carbon nanotubes, graphene, fullerene, and derivatives or functionalised variants thereof. Uncoated carbon nanotubes (CNTs) have very high thermal resistance, but can be etched by hydrogen plasma induced by EUV radiation within the lithography apparatuses. This etching limits the lifetime of the CNTs and therefore the pellicle. Different types of carbon nanotubes have different electronic band structures and therefore have different electrical conductivities and different emissivities. Carbon nanotubes having higher emissivity operate at lower temperatures than semi-conducting or non-conducting carbon nanotubes. Depending on the application, it is desirable to manufacture CNT films which comprise a large amount of CNTs having a specific property such as conductivity emissivity or etching resistance. Also, it is desirable to have an apparatus for the treatment of ready-made CNT films to selectively keep a large amount of CNTs having the specific property.

Existing synthesis methods of single wall carbon nanotubes (SWCNTs) or multi-wall carbon nanotubes (MWCNTs) produce a mixture of CNTs with a distribution of chiral indices (m, n) centred on a mean (where m, n are positive integers). Post-synthesis treatments can then be applied to attempt to separate different nanotubes from one another. Techniques used include physical separation techniques based on electrophoresis or ultracentrifugation, as well as chemical routes including covalent or non-covalent functionalization or oxidation by hydrogen peroxide. However, these techniques do not have a high enough yield or are unable to be scaled sufficiently.

As mentioned, CNTs with a pre-selected bonding configuration or chirality can behave differently in a hydrogen plasma environment. For example, CNTs with a zigzag chirality (m, 0) show a higher resistance to etching in hydrogen plasma environment than CNTs with other chirality, which makes them most suitable for films of uncoated CNTs having superior EUV transmission. Conversely, CNTs with armchair chirality (m, m) have a better thermal emissivity than CNTs with other chirality, which makes them more suitable for coated CNT applications having a superior thermal resistance. Therefore, depending on the conditions in the EUV lithographic apparatus it may be advantageous to have a pellicle or a membrane which comprises substantially CNTs with zigzag chirality, or CNTs with armchair chirality, or a combination of zigzag and armchair chirality having a specific ratio depending on the environmental conditions.

The apparatus according to the second aspect of the present invention allows for a carbon nanotube membrane to be treated in order to keep a substantial amount of CNTs with a pre-selected bonding configuration or chirality. The heat source may comprise at least one of a laser and an oven. The apparatus treats the membrane for example by laser heating and reaction with the reactive gas or by exposure to plasma since armchair carbon nanotubes are more rapidly etched by hydrogen plasma than zigzag nanotubes. Such treatment can be used for obtaining membranes comprising a substantial amount of zigzag chiral CNTs. In an alternative, the apparatus treats the membrane for example by oven or hot plate heating and reaction with the reactive gas. Such treatment can be used for obtaining membranes comprising a substantial amount of armchair chiral CNTs. The carbon nanotube membrane comprises nanotubes having different electrical conductivities and therefore the carbon nanotube membrane is not at a single temperature, but rather the less-conductive and therefore less emissive nanotubes achieve a higher temperature than the more conductive and therefore more emissive nanotubes. As such, the reactive gas preferentially reacts with the hotter carbon nanotubes, which are consequently consumed in the reaction. At below a critical temperature, there will be no reaction between the relatively inert carbon nanotubes and the reactive gas, or only a very slow reaction. As such, by selecting the heating means and whether a plasma is used to treat the membrane, it is possible to select certain types of nanotube to be retained or depleted from the membrane.

As such, it is possible to prepare a treated carbon-based, preferably carbon nanotube, membrane in which the less-emissive carbon nanotubes have been removed. An advantage of this is that the resultant membrane when used as a pellicle in a lithography apparatus, particularly an EUV lithography apparatus, operates at a lower temperature and has a longer lifespan within the lithography apparatus. In addition, since the membrane is more uniform in that different types of carbon nanotubes have been removed, during use, the transmissivity of the membrane is less susceptible to drift compared to membranes which have not been treated. It is also possible to provide a protective coating to the carbon nanotubes since they will operate at lower temperatures and therefore the risk of the protective coating becoming damaged is reduced or eliminated.

The apparatus according to the second aspect of the present invention allows for the rapid and efficient selective depletion of carbon nanotubes which have an undesired bonding configuration or chirality (m, n). Example of an undesired chirality may be any chirality (m, n) different than zigzag chirality (m, 0), or any chirality (m, n) different than armchair chirality (m, m), or any chirality (m, n) different than zigzag (m, 0) and armchair (m, m) chirality. In addition, the apparatus allows for the selective depletion of carbon nanotubes having different diameters. For example, carbon nanotubes having smaller diameters are able to more rapidly be depleted than carbon nanotubes having larger diameters. For example, the carbon nanotubes may have a diameter of from around 2 nm to around 10 nm.

In addition, existing methods and apparatuses for producing a substantially monodisperse population of carbon nanotubes would not be suitable for application to a membrane or a pellicle as they would destroy the structure of the membrane. By being able to manufacture a carbon nanotube membrane which comprises an increased proportion of conductive, metallic carbon nanotubes, the membrane has a higher thermal emissivity and electron emissivity resulting in the temperature of the carbon nanotube membrane being lower in use due to increased thermal emissions at the same level of EUV absorption. This may increase the lifetime of the membrane and may enable the use of a coating to prevent plasma etching. Armchair chirality (m, m) carbon nanotubes are particularly suitable to provide emissive membranes suitable for being coated to prevent or at least reduce plasma etching. Previously, the use of a coating on carbon nanotubes which were non-emissive could cause damage to the coating and failure of the membrane. Furthermore, such treated carbon nanotube membranes emit more electrons per carbon nanotube, which reduces the surrounding plasma potential, thereby reducing on energy and etch yield, again resulting in increased lifetime of the membrane. On the other hand, when uncoated carbon nanotubes are used to form a membrane, it may be preferable to have the membrane made of semiconducting (zigzag) carbon nanotubes having a larger diameter as this reduces the rate of hydrogen-plasma etching since zigzag carbon nanotubes with a greater diameter are more resistant to hydrogen plasma etching that carbon nanotubes having a smaller diameter.

The apparatus may include a support for supporting a carbon-based membrane. Depending on how the carbon-based membrane has been prepared, it may be in the form of a free standing membrane or may be supported by a substrate. The support may support the carbon-based membrane around the perimeter. The support may be in the form of a plate on which the carbon based membrane is provided. The support may be in the form of a grid supporting the CNT film.

The apparatus may be configured to scan the laser beam. Depending on the size of the carbon nanotube membrane and the diameter of the laser beam, the apparatus may be configured to move the laser relative to any carbon nanotube membrane being treated. Laser heating is advantageous since it can be precisely applied to the desired areas of the membrane and can be used to selectively heat up certain of the carbon nanotubes included in the membrane. Laser heating and reaction with gas may be used to select armchair chirality carbon nanotubes. Other forms of heating, such as in an oven, and/or reacting with plasma would result in the selection of zigzag chirality carbon nanotubes.

The laser may be configured to heat at least a portion of a carbon nanotube to a temperature sufficient to allow it to react with the reactive gas. The power of the laser may be selected to heat up the carbon nanotube membrane to the desired reaction temperature. The exact power used may be varied and will depend on factors including, but not limited to, the diameter of the laser beam and the nature of the carbon nanotube membrane. It will be appreciated that different carbon nanotubes within the membrane will be heated to different temperatures due to the physical differences between them, so it is the carbon nanotubes which are intended to be depleted which need to be heated to the desired temperature rather than the entirety of the carbon nanotube membrane. Indeed, it is this differential heating which provides for selective removal of certain carbon nanotubes. Any suitable wavelength of light may be used to heat the carbon nanotube membrane. One example is an 810 nm laser, although it will be appreciated that the invention is not particularly limited to the specific wavelength of light used.

The heat source may be operable to heat at least a portion of a carbon nanotube membrane to at least 350° C., preferably to at least 380° C. Again it will be appreciated that not all of the membrane necessarily needs to be heated to these temperatures, but rather only the particular nanotubes which are being removed from the membrane. At these temperatures, certain of the nanotubes are able to react with the reactive gas and be etched away. The carbon may be removed by the production of gaseous carbon species, including carbon oxides and hydrocarbons.

The reactive gas may be a reductive gas. A reductive gas is a gas which has an overall reducing effect on a substrate.

The reactive gas may also be a plasma, such as a hydrogen plasma. In such case the gas supplied by the gas supply may be an inert gas (e.g. H2) which then may be rendered to become a reactive gas in the form of plasma (e.g. a hydrogen plasma). This alternative is mentioned below as “plasma formed from the reactive gas”.

The gas supply may be configured to provide clean dry air, hydrogen, a mixture of hydrogen and oxygen, a mixture of hydrogen and nitrogen, or a mixture of hydrogen, nitrogen and oxygen. The gas may contain other non-reactive gases, such as argon or helium. Preferably the gas comprises hydrogen and oxygen. The reactive gas may essentially consist of hydrogen and oxygen. Unavoidable impurities may be present. Although in some cases the gas may comprise a mixture of hydrogen and oxygen, the oxygen may be provided in an amount such that the gas mixture overall is reducing. The mixture of hydrogen and oxygen may comprise up to about 1 vol % oxygen, up to about 2 vol % oxygen, up to about 3 vol % oxygen, up to about 4 vol % oxygen, or up to about 5 vol % oxygen, with the balance being hydrogen. The presence of a small amount of oxygen increases the rate at which the carbon nanotubes are selectively depleted. However, since the overall gas may be reducing, any oxides are removed from the carbon nanotubes. An advantage of a reducing environment is that oxygen present within the membrane may be removed, albeit at a cost of hydrogen being present in the membrane, which may speed up the rate of etching by hydrogen plasma. A further advantage of removal of a proportion of the carbon nanotubes is that the transmissivity of the resulting membrane to EUV radiation is increased due to the removal of material from the membrane. In other embodiments, the gas may be an oxidising gas. A benefit of an oxidising environment is that no hydrogen is present with the membrane following treatment, albeit with the drawback that oxygen will be present within the membrane, which reduces EUV transmissivity.

The laser may be configured to illuminate the carbon-based membrane with an incident radiation intensity of from about 1 W cm⁻² to about 40 W cm⁻².

The oven may be configured to heat the carbon-based membrane to a temperature of from about 350° C. to about 1200° C.

According to a third aspect of the present invention, there is provided a method for treating a carbon-based membrane, the method including: i) providing a carbon-based membrane; ii) heating the carbon-based membrane with a heat source; iii) providing a reactive gas: and iv) reacting the reactive gas or a plasma formed from the reactive gas with at least a portion of the carbon-based membrane to selectively deplete carbon nanotubes with a (m, n) chirality other than (m, 0) and (m, m) chirality from the carbon-based membrane, such that the treated carbon-based membrane comprises ≥90% of carbon nanotubes having zigzag and/or armchair chirality.

The method according to the third aspect of the present invention provides a method for treating a carbon-based membrane, preferably a carbon nanotube membrane, by selectively depleting some of the carbon nanotubes comprising the membrane. This is achieved by illuminating the carbon nanotube membrane with laser light to selectively heat the less emissive carbon nanotubes and providing a reactive gas which is able to react with the hotter carbon nanotubes to selectively deplete them, or by exposure to a hydrogen plasma which selectively depletes armchair chirality carbon nanotubes. Preferably, the method provides a substantially monodisperse carbon nanotube membrane. Previous methods of separating different carbon nanotubes would not be suitable for treating a carbon nanotube membrane as they would necessarily result in the destruction of the membrane, which would then have to be re-formed in a different process. This process is able to efficiently selectively remove carbon nanotubes from the carbon nanotube membrane resulting in a membrane which comprises a significantly increased proportion of emissive carbon nanotubes. As a result of this, the operating temperature of a pellicle comprising such a membrane is lower than one comprising an untreated carbon nanotube membrane, all else being equal. This can be done outside of the lithography apparatus and prior to the membrane being installed in a lithography apparatus. The carbon nanotube membrane comprises a mixture of conductive and non-conductive carbon nanotubes. The heating of the carbon nanotube membrane selectively heats certain of the carbon nanotubes to above the temperature at which they react with the reactive gas whilst the other carbon nanotubes remain below that temperature, thereby allowing selective removal of the specific carbon nanotubes which reach the higher temperature. There would be no such selective removal within an EUV lithography apparatus since the membrane (as part of the pellicle) would be heated to well in excess of the temperature required to result in etching of the carbon nanotubes. On the other hand, where a plasma is applied, the armchair chirality carbon nanotubes may be preferentially depleted, resulting in a membrane with an increased proportion of zigzag chirality carbon nanotubes, which are more resistant to plasma etching.

The carbon-based membrane may comprise carbon nanotubes. The carbon nanotubes may have different bonding configurations or chiralities. The carbon nanotubes may comprise emissive and non-emissive single or multi-wall carbon nanotubes (such as double wall carbon nanotubes). Depending on the structure of the carbon nanotubes, they are commonly classified as being emissive or non-emissive. This is dependent on whether they are conductive (emissive) or non-conductive (non-emissive). The method comprises selectively removing non-conductive carbon nanotubes from a carbon nanotube membrane or selectively removing conductive carbon nanotubes from a carbon nanotube membrane.

The method may include heating at least a portion of the carbon nanotube membrane to at least 350° C., preferably to at least 380° C., preferably to less than 1200° C. Again, it will be appreciated that it only certain of the nanotubes which are heated to these temperatures, rather than all of the nanotubes since it is the differential heating of the nanotubes which provides the ability to selectively deplete certain nanotubes. The membrane can become damaged if it is heated to too high a temperature, so it is preferable to keep the temperature to below around 1200° C.

The reactive gas may be a reductive gas. The reactive gas may comprise clean dry air; hydrogen; a mixture of hydrogen and oxygen; a mixture of hydrogen and nitrogen; or a mixture of hydrogen, nitrogen, and oxygen. The reactive gas may be clean dry air; hydrogen; a mixture of hydrogen and oxygen; a mixture of hydrogen and nitrogen; or a mixture of hydrogen, nitrogen, and oxygen. In embodiments, the gas may be an oxidising gas.

The method may include scanning a laser across the carbon nanotube membrane. The invention is not particularly limited to whether it is one or both of the laser and the carbon nanotube membrane which are moved relative to the other. By scanning the laser, specific portions of the carbon nanotube membrane can be heated up and treated to selectively deplete certain types of carbon nanotube. As such, the method may include selectively depleting one or more carbon nanotubes of the carbon nanotube membrane. By depleting certain of the nanotubes, it is possible to provide a more uniform membrane which has a higher emissivity and therefore operates at a lower temperature for a given power. In addition, there is a lower amount of drift in the transmissivity of a pellicle comprising such a membrane during use in a lithography apparatus.

The method may include illuminating the carbon nanotube membrane with an incident radiation intensity of from about 1 W cm⁻² to about 40 W cm⁻². Preferably, the incident laser intensity is above about 8.4 W cm⁻² in order to sufficiently heat the non-emissive carbon nanotubes. It will be appreciated that the laser referred to in any aspect of the present invention may be configured to provide laser energy at such intensities. Higher intensities than 40 W cm⁻² are liable to overheating the membrane, but could be used if cycled.

According to a fourth aspect of the present invention, there is provided a carbon nanotube membrane according to the first aspect of the present invention or treated according to the method of the third aspect of the present invention.

By having been treated by the method according to the third aspect of the present invention, substantially all of the undesired bonding configuration or chirality (m, n) carbon nanotubes may be removed from the membrane. Throughout the present disclosure, by substantially all, it is understood than more than around 65%, preferably more than around 75%, even more preferably more than around 90%, more than around 95%, more than around 98%, more than around 99% of the feature referred to, which in the present case is the amount of carbon nanotubes having an undesired bonding configuration or chirality (m, n) are removed. As such, the treated CNT membrane comprises more than 70%, preferably more than 80%, more preferably more than 90%, more than 95%, more than 98%, or more than 99% of carbon nanotubes with zigzag and/or armchair chirality.

As described, there may be provided a carbon nanotube membrane for use as a pellicle in a lithographic apparatus, wherein the carbon nanotube membrane comprising substantially of carbon nanotubes having a pre-selected bonding configuration or chirality. The carbon nanotube membrane may therefore be homochiral.

By comprising substantially of, it is understood that greater than around 70%, greater than around 75%, greater than around 80%, greater than around 85%, greater than around 90%, greater than around 95%, greater than around 98%, or greater than around 99% of the membrane comprises carbon nanotubes having the desired pre-selected bonding configuration or chirality, for example a zigzag chirality. For an armchair chirality, the term “by comprising substantially of”, it is understood that greater than around 35%, greater than around 50%, greater than around 70%, greater than around 75%, greater than around 80%, greater than around 85%, greater than around 90%, greater than around 95%, greater than around 98%, or greater than around 99% of the membrane comprises carbon nanotubes having the desired pre-selected bonding configuration or chirality.

By comprising substantially of carbon nanotubes having a pre-selected bonding configuration or chirality, there are advantages when used as a pellicle in a lithographic apparatus.

The carbon nanotube membrane may comprise substantially of carbon nanotubes having zigzag (m,0) chirality. Carbon nanotubes having zigzag chirality are semi-conducting and therefore are classed as being non-emissive. As such a pellicle comprising carbon nanotubes having zigzag chirality is less emissive than one which comprises more emissive types of carbon nanotube. Whilst this means that the operating temperature will be higher than that of a carbon nanotube membrane comprising emissive carbon nanotubes all else being equal, zigzag carbon nanotubes are able to withstand higher operating temperatures. As such, an advantage of such a pellicle is that it is able to withstand high operating temperature, such as for example up to 1900 K, and additionally since the pellicle essentially consists of one type of carbon nanotube, there is less drift in transmissivity than would be the case for a pellicle comprising a mixture of different types of carbon nanotube. In addition, semiconducting carbon nanotubes are etched at a slower rate than conductive carbon nanotubes.

The carbon nanotube membrane may comprise substantially of carbon nanotubes having armchair chirality. Carbon nanotubes having armchair chirality are conductive and therefore are classed as being emissive. As such, a pellicle comprising carbon nanotubes having armchair chirality is more emissive than one which comprises less emissive types of carbon nanotube. This means that the operating temperature will be lower than that of a carbon nanotube membrane comprising non-emissive carbon nanotubes all else being equal. As such, whilst such emissive carbon nanotubes are less able to withstand high temperatures, they are able to operate at lower temperatures. In addition since the pellicle essentially consists of one type of carbon nanotube, there is less drift in transmissivity than would be the case for a pellicle comprising a mixture of different types of carbon nanotube.

The chirality of a carbon nanotube membrane may also be pre-determined by appropriate selection of a template crystal which promote growth of a given (m, n) chirality.

According to a fifth aspect of the present invention, there is provided a pellicle comprising a carbon nanotube membrane according to the first or fourth aspect of the present invention or treated with the apparatus or method of the second or third aspects of the present invention.

By having a pellicle material comprising a carbon nanotube membrane consisting essentially of carbon nanotubes having a pre-selected bonding configuration or chirality, there is a reduced rate of drift in transmissivity during operation in a lithography apparatus. The pellicle material can be selected to have lower emissivity and therefore a higher operating temperature but with a higher ability to withstand high temperatures (e.g. up to 1900K), or to have a higher emissivity and therefore a lower operating temperature but with a lower ability to withstand higher temperatures (e.g. up to 1200K (around 927° C.). The higher-temperature variant will be more plasma resistant due to its chirality, whereas the lower-temperature variant will be preferred when a protective coating is applied.

According to a sixth aspect of the present invention, there is provided a lithographic apparatus comprising a pellicle or carbon nanotube membrane according to any of the first to fifth aspects of the present invention.

According to a seventh aspect of the present invention, there is provided the use of a method according to the third aspect of the present invention in a lithographic method or the use of a pellicle or carbon nanotube membrane according to any of the first, or fourth to sixth aspects of the present invention.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention;

FIG. 2 is a schematic depiction of an apparatus according to an embodiment of the present invention; and

FIG. 3 is a schematic depiction of a method according to an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

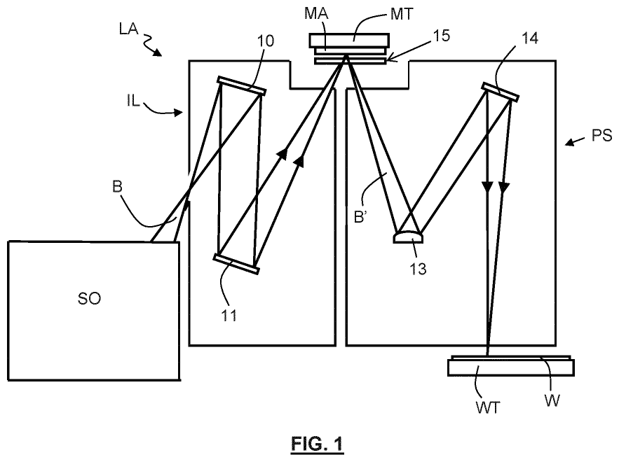

FIG. 1 shows a lithographic system including a pellicle 15 comprising a carbon nanotube membrane according to one aspect of the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer configured to transmit at least 90% of incident EUV radiation. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

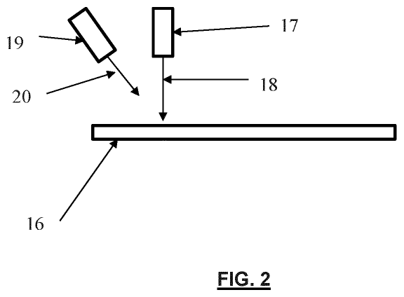

FIG. 2 is a schematic depiction of an apparatus according to an aspect of the present invention. The apparatus comprises a support structure 16. The support structure 16 can be of any suitable configuration to support a carbon nanotube membrane. As such, the support structure 16 may be configured to support the perimeter of a membrane or may be in the form of a plate or a grid on which the membrane rests. A laser 17 is provided which is configured to direct a laser beam 18 towards the support structure 16. As such, when a carbon nanotube membrane is present, the laser light illuminates the membrane. The apparatus also includes a gas supply 19 which provides a reactive gas 20. The exact location and orientation of the gas supply 19 may be other than that depicted in FIG. 2. The apparatus may include a chamber (not shown) in which the remaining components of the apparatus are disposed. The chamber may be configured to provide a controlled atmosphere therein.

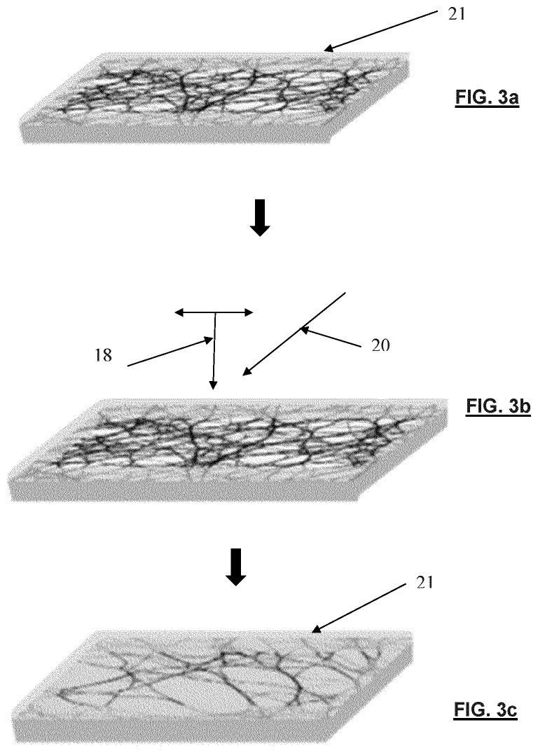

FIGS. 3a to 3c depict a method according to one embodiment of the present invention. FIG. 3a depicts a carbon nanotube membrane 21 which comprises both emissive and non-emissive single wall carbon nanotubes. In the next step as depicted in FIG. 3b, the laser beam 18 is used to illuminate the carbon nanotube membrane to cause selective heating of the non-emissive nanotubes. A stream of reactive gas 20 is also provided which depletes the carbon nanotubes which have chirality other than zigzag which are heated by the laser beam 18. The laser beam 18 can be moved relative to the carbon nanotube membrane 21 in order to heat different portions of the membrane 21. As depicted in FIG. 3c, after the membrane has been treated, the non-emissive carbon nanotubes have been selectively removed leaving a membrane comprising emissive single wall carbon nanotubes. In other embodiments, an oven may be used to heat the membrane. According to one embodiment of the present invention the carbon nanotube membrane comprises both emissive and non-emissive multi-wall carbon nanotubes, for example double wall carbon nanotubes. Preferably, the carbon nanotube membrane of the invention comprises greater than around 65% of multi-wall carbon nanotubes having zigzag (m, 0) chirality and/or armchair (m, m) chirality.

The present invention provides means for improving the stability of carbon nanotube membranes within EUV lithography apparatuses and allows for the selective depletion of certain types of carbon nanotubes from a membrane comprising both emissive and non-emissive carbon nanotubes.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A carbon nanotube membrane comprising carbon nanotubes having a pre-selected bonding configuration or (m, n) chirality, wherein the carbon nanotube membrane comprises a substantial amount of carbon nanotubes having zigzag (m, 0) chirality and/or armchair (m, m) chirality.

2. The carbon nanotube membrane of claim 1, wherein the carbon nanotube membrane comprises greater than around 65% of carbon nanotubes having zigzag (m, 0) chirality and/or armchair (m, m) chirality.

3. The carbon nanotube membrane of claim 2, wherein the carbon nanotube membrane comprises greater than around 70% of carbon nanotubes having zigzag (m, 0) chirality and/or armchair (m, m) chirality.

4. The carbon nanotube membrane of claim 1, wherein the carbon nanotubes have a diameter of from around 1 nm to around 15 nm.

5. The carbon nanotube membrane of claim 1, wherein any nanotubes of armchair (m, m) chirality include an etch-protective coating.

6. The carbon nanotube membrane of claim 1, wherein the membrane has a thickness of less than 100 nm.

7. The carbon nanotube membrane of claim 1, wherein the membrane has an EUV transmissivity of greater than around 90%.

8. The carbon nanotube membrane of claim 1, wherein the membrane is homochiral.

9. An apparatus for the treatment of a carbon-based membrane to obtain a pre-selected bonding configuration or chirality, the apparatus including a heat source and a gas supply, wherein the heat source and the gas supply are configured to treat at least part of the carbon-based membrane with a reactive gas, or a plasma formed from the reactive gas, to selectively remove carbon nanotubes with a (m, n) chirality other than (m, 0) and (m, m) chirality from the carbon-based membrane, such that the treated carbon-based membrane comprises 65% of carbon nanotubes having zigzag and/or armchair chirality.

10. The apparatus according to claim 9, wherein the heat source comprises a laser and/or an oven.

11. The apparatus according to claim 9, further comprising a support configured to support the carbon-based membrane.

12. The apparatus according to claim 9, wherein the heat source is configured to heat the carbon-based membrane to a temperature sufficient to allow it to react with the reactive gas.

13. The apparatus according to claim 12, wherein the heat source is operable to heat at least a portion of a carbon-based membrane to at least 350° C.

14. The apparatus according to claim 9, wherein the reactive gas is a reductive gas.

15. The apparatus according to claim 9, wherein the gas supply is configured to provide: clean dry air; hydrogen; a mixture of hydrogen and oxygen; a mixture of hydrogen and nitrogen; or a mixture of hydrogen, nitrogen, and oxygen.

16. The apparatus according to claim 9, wherein the reactive gas comprises up to about 1 vol % oxygen with the balance being hydrogen.

17. The apparatus according to claim 10, comprising the laser and wherein the laser is configured to illuminate the carbon-based membrane with an incident radiation intensity of from about 1 W cm⁻² to about 40 W cm⁻².

18. The apparatus according to claim 10, comprising the oven and wherein the oven is configured to heat the carbon-based membrane to a temperature of from about 350° C. to about 1200° C.

19. A method for treating a carbon-based membrane, the method including:
heating a carbon-based membrane with a heat source; and
reacting a reactive gas, or a plasma formed from the reactive gas, with at least a portion of the carbon-based membrane to selectively deplete carbon nanotubes with a (m, n) chirality other than (m, 0) and (m, m) chirality from the carbon-based membrane, such that the treated carbon-based membrane comprises ≥65% of carbon nanotubes having zigzag and/or armchair chirality.

20.-24. (canceled)

25. A pellicle comprising a carbon nanotube membrane according to claim 1.

26.-28. (canceled)
